(19) United States
(12) Patent Application Publication
(10) Pub. No.: US 2007/0089672 A1
(43) Pub. Date: Apr. 26, 2007

(54) Substrate placing mechanism

(76) Inventors: Akinori Shimamura, Nirasaki-Shi (JP); Kentaro Asakura, Nirasaki-Shi (JP)

Correspondence Address: SMITH, GAMBRELL & RUSSELL, 1850 M STREET, N.W., SUITE 800, WASHINGTON, DC, 20036, US

(21) Appl. No.: 11/527,730

(22) Filed: Sep. 27, 2006

(30) Foreign Application Priority Data
Sep. 30, 2005 (JP) 2005-288295
Mar. 30, 2006 (JP) 2006-095167

(51) Int. Cl. B05C 11/11; C23C 8/00; C23C 14/00; C23C 14/32

(52) U.S. Cl. 118/504; 427/585; 204/192.12

(57) ABSTRACT

The present invention is a substrate placing mechanism including: a placing stage provided for placing a substrate to be processed thereon in a processing container in which a processing atmosphere is formed by a process gas, the placing stage having a plurality of pin-inserting holes; a plurality of lifter-pins, each of which is inserted into and vertically movable in each of the plurality of pin-inserting holes; an elevating member that supports the plurality of lifter-pins; and an elevating mechanism that causes the lifter-pins to vertically move via the elevating member. Each of the plurality of pin-inserting holes has a circular protrusion at an opening part of a lower end thereof. The circular protrusion protrudes inwardly and circularly. Each of the plurality of lifter-pins has a diameter-increasing part configured to be supported by the circular protrusion to close the opening part when a corresponding lifter-pin is caused to move down.

### FIELD OF THE INVENTION

This invention relates to a substrate placing mechanism that includes a placing stage for placing a substrate to be processed thereon, and that causes the substrate to be processed to move up and down by means of lifter-pins which are caused to vertically move by an elevating mechanism. In addition, this invention relates to a substrate processing apparatus including such a substrate placing mechanism.

### BACKGROUND ART

In general, an apparatus for conducting a process, for example a CVD (Chemical Vapor Deposition) process, a film-forming process and/or an etching process, to a substrate to be processed, for example a semiconductor wafer, is provided with a processing container, into which a process gas is supplied for conducting the process to the wafer (substrate). In the processing container, a placing mechanism including a placing stage for placing the wafer to be processed thereon is provided. The placing mechanism has a role of receiving and delivering the wafer between the placing stage and a conveying mechanism (not shown) that conveys the wafer into the processing container.

A conventional wafer placing mechanism 1 is explained with reference to FIGS. 9A and 9B. In these drawings, the sign 11 represents a placing stage, and the sign 12 represents a placing surface of the placing stage 11 for a wafer W. For example, the placing stage 11 has three through-holes at regular intervals along a circumference thereof. Each through-hole runs vertically. A sleeve 13 is fitted and fixed in each through-hole. A lifter-pin 15 is inserted into each sleeve 13. A pin base 16 is provided below the lifter-pin 15. The pin base 16 is connected to a driving part, not shown, via a lifter arm 17.

When the lifter-pin 15 is not in a operation for receiving or delivering the wafer, as shown in FIG. 9A, an upper end of the lifter-pin 15 is located below the placing surface 12 of the placing stage 11. The position is called “home position”.

On the other hand, when the wafer placing mechanism 1 receives the wafer W from the conveying mechanism (not shown), because of elevation of the lifter arm 17, as shown in FIG. 9B, the pin base 16 vertically pushes up the respective lifter-pins 15 from their home positions. Thus, as shown in FIG. 9B, the lifter-pins 15 protrude from the placing stage 11. Then, the protruding lifter-pins 15 support a reverse surface of the wafer W conveyed into the processing container by means of the conveying mechanism. Then, the pin base 16 is caused to move down. When the pin base 16 moves down, the lifter-pins 15 move down while supporting the wafer W thereon. When the lifter-pins 15 return to their home positions, the wafer W is placed on the placing stage 11.

Herein, in order for the lifter-pin 15 to smoothly move up and down in the sleeve 13, there is a gap with a certain size between an inner wall of the sleeve 13 and the lifter pin 15. Then, the lifter pin 15 is adapted to move up and down in the sleeve 13, with causing a portion thereof to come in contact with the inner wall of the sleeve 13.

However, the above conventional placing mechanism has the following problems.

For example, in a film-forming apparatus wherein a Ti (Titan) film as an electric conductive film is formed on a wafer W by means of a CVD process, the wafer W is conveyed into a processing container in the film-forming apparatus, and is placed on the placing stage 11. Then, a TiCl₄ gas as a film-forming gas is supplied into the processing container. In the case, a portion of the TiCl₄ gas goes under the placing stage 11. Herein, the TiCl₄ gas has a feature wherein the TiCl₄ gas flows into a gap between solid bodies and tends to form deposits in the gap. Thus, as shown by arrows in FIG. 10A, when the TiCl₄ gas flows from a lower side of the placing stage 11 into a gap between the lifter-pin 15 and the sleeve 13, as shown in FIG. 10B, deposits 19 may be formed so as to clog the gap. If such deposits 19 are formed and accumulated, it becomes impossible for the lifter-pin 15 to smoothly move in the sleeve 13. That is, it becomes impossible for the lifter-pin 15 to move down to its home position. Alternatively, the lifter-pin 15 may stick to the sleeve 13. In such a condition, if the lifter-pin 15 is forcibly lifted up by the pin base 16, the lifter-pin 15 may be broken.

In addition, a CVD film-forming apparatus may use plasma. In the case, if electrically conductive deposits 19 are generated from a gas such as a TiCl₄ gas and stick to the gap between the lifter-pin 15 and the sleeve 13, an electric potential difference is generated between the lifter pin 15 and the placing stage 11. Then, there is possibility that abnormal discharge occur around the lifter-pin 15. In the case, the lifter-pin 15 may be deteriorated, and breakage thereof may be promoted.

The phenomenon that the deposits 19 generated from the film-forming gas clog the gap between the lifter-pin 15 and the sleeve 13 is not limited to the above process. For example, in a placing mechanism in an etching apparatus, particles of reaction product by an etching process may clog the gap, which may cause the same problem.

In order to prevent the above breakage of the lifter-pin 15 in a placing mechanism provided in a film-forming apparatus or an etching apparatus, it is effective to replace or clean the lifter-pin 15 and the sleeve 13 every short period. However, a replacing operation and/or a cleaning operation of the lifter-pin 15 and the sleeve 13 is troublesome, and is one factor in increasing load of a maintenance operation.

Japanese Patent Laid-Open Publication No. 2004-343032 discloses a placing mechanism wherein a lower end of a sleeve fixed in a pin-inserting hole protrudes under a placing stage so that a process gas is prevented from going into the above gap. However, the placing mechanism is not sufficient to solve the above problems.

In addition, in a CVD film-forming apparatus, after the processing container is cleaned and then before a (first) wafer is conveyed, in order to conduct a uniform process to respective wafers, atmosphere in the processing container may be made close to that at a film-forming process. Specifically, for example, a film-forming gas such as a TiCl₄ gas is supplied into the processing container, so that the placing surface 12 may be precoated. In the case, as shown by arrows in FIG. 11A, the TiCl₄ gas may go into the sleeve 13 from an upper side of the placing stage 11. Then, as shown in FIG. 11B, deposits 19 may be formed in the vicinity of a tip end of the lifter-pin 15 located in its home position. Then, when the lifter-pin 15 moves up to receive a wafer W conveyed into the processing container, as shown in FIG. 11C, the deposits 19 may be peeled off from the sleeve 13 and the lifter-pin 15, and pushed up along the inner wall of the sleeve 13, and laid on the placing surface 12. Then, if the lifter-pin 15 moves down while holding the wafer W, the deposits 19 may stick to the reverse surface of the wafer as particles. This is a factor of particle contamination.

### SUMMARY OF THE INVENTION

The present invention has been created to solve the above problems. The object of the present invention is to provide a substrate placing mechanism wherein accumulation of reaction product caused by supply of a process gas is inhibited in a gap between a pin-inserting hole provided in a placing stage and a lifter-pin movable in the pin-inserting hole for receiving and delivering a wafer from and to the placing stage.

In order to achieve the above object, the invention is a substrate placing mechanism comprising: a placing stage provided for placing a substrate to be processed thereon in a processing container in which a processing atmosphere is formed by a process gas, the placing stage having a plurality of pin-inserting holes; a plurality of lifter-pins, each of which is inserted into and vertically movable in each of the plurality of pin-inserting holes; an elevating member that supports the plurality of lifter-pins; and an elevating mechanism that causes the plurality of lifter-pins to vertically move via the elevating member; wherein each of the plurality of pin-inserting holes has a circular protrusion at an opening part of a lower end thereof, the circular protrusion protruding inwardly and circularly; and each of the plurality of lifter-pins has a diameter-increasing part that is configured to be supported by the circular protrusion so as to close the opening part when a corresponding lifter-pin is caused to move down.

According to the present invention, when the lifter-pin moves down, the diameter-increasing part of the lifter-pin is supported by the circular protrusion of the pin-inserting hole, so that the opening part of the pin-inserting hole is closed. Thus, even if a process gas goes under the placing stage on which a substrate to be processed is placed, the process gas is prevented from flowing from a lower end of the pin-inserting hole into an inside thereof. Thus, it is inhibited that reaction product be accumulated at a gap between the lifter-pin and the pin-inserting hole. Thus, it is inhibited that the moving up and down of the lifter-pin be disturbed. As a result, frequency of maintenance operation for ensuring a normal operation of the lifter-pin, such as a cleaning operation and/or a replacing operation of components forming the lifter-pin and the pin-inserting hole, may be reduced.

It is preferable that an upper surface of the circular protrusion is funneled in order to guide the diameter-increasing part to position the lifter-pin at a center of the pin-inserting hole. In the case, it is more preferable that a lower surface of the diameter-increasing part is tapered.

In addition, it is preferable that a portion of the lifter-pin that is adapted to protrude from the pin-inserting hole when the substrate is supported by the lifter-pin has a diameter smaller than that of the diameter-increasing part. The smaller diameter portion is preferably formed not to come into contact with the inner surface of the pin-inserting hole because the diameter-increasing part inhibits the inclination even when the lifter-pin inclines in the pin-inserting hole.

That is, if a portion of the lifter-pin located upper than the diameter-increasing part is made thinner so that the diameter-increasing part maintains the vertical posture of the lifter-pin, the smaller-diameter portion of the upper portion doesn't rub the pin-inserting hole or rubs to a small extent. Thus, it is inhibited that the reaction product stuck in the pin-inserting hole be pushed up onto the placing surface of the placing stage to contaminate the substrate as particles.

In addition, it is preferable that a second diameter-increasing part is provided on each of the plurality of lifter-pins, the second diameter-increasing part being located upper than the diameter-increasing part, the second diameter-increasing part being maintained in the pin-inserting hole even when the substrate is received by the lifter-pin.

In addition, it is preferable that the plurality of lifter-pins is provided separately from the elevating member, ,and that the diameter-increasing part is supported by the circular protrusion by weight of the lifter-pin.

In addition, the present invention is a substrate processing apparatus comprising: a processing container; a substrate placing mechanism having any of the above features provided in the processing container; and a process-gas supplying part that supplies a process gas into the processing container in order to conduct a process to a substrate to be processed placed on the substrate placing mechanism.

### BRIEF DESCRIPTION OF THE DRAWINGS

FIG. 1 is a schematic view showing an overall structure of a film-forming apparatus provided with an embodiment of a substrate placing mechanism according to the present invention;

FIG. 2 is a schematic sectional view showing the embodiment of a substrate placing mechanism according to the present invention;

FIG. 3 is a perspective view of a sleeve and a lifter-pin;

FIG. 4 is a sectional view for explaining an example of dimensions of the sleeve and the lifter-pin;

FIGS. 5A and 5B are schematic views for explaining an operation wherein the lifter-pin receives a wafer;

FIGS. 6A to 6C are sectional views for explaining another structure of the lifter-pin;

FIG. 7 is a view for explaining an example of dimensions of the lifter-pin;

FIGS. 8A and 8B are schematic sectional views showing another embodiment of a substrate placing mechanism according to the present invention;

FIGS. 9A and 9B are schematic views for explaining an operation wherein a substrate is delivered onto a conventional substrate placing mechanism;

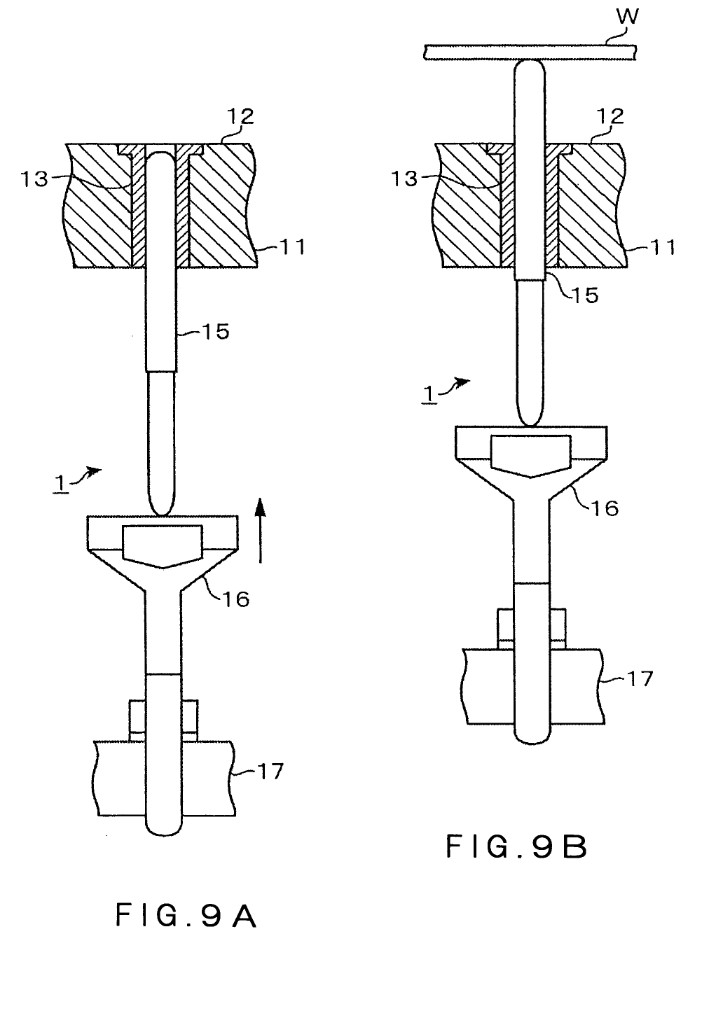

FIGS. 10A and 10B are schematic views for explaining generation of deposits at a gap between a sleeve and a lifter-pin of the conventional substrate placing mechanism; and

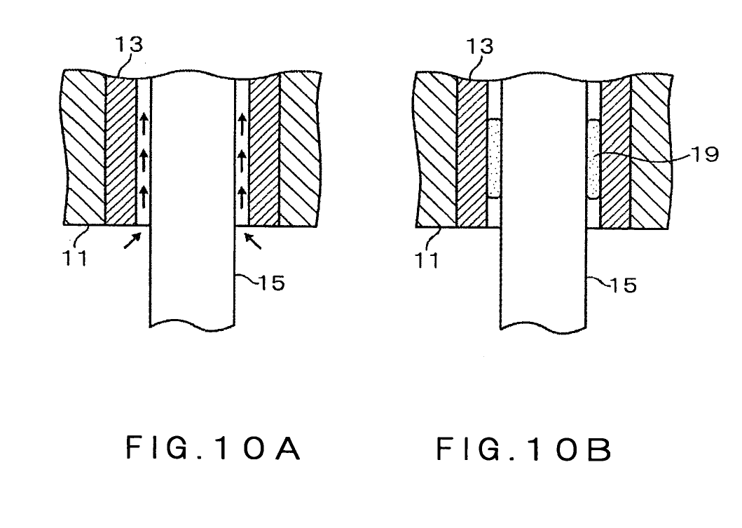

FIGS. 11A to 11C are schematic views for explaining movement of the deposits onto the placing stage of the substrate placing mechanism when the lifter-pin moves up.

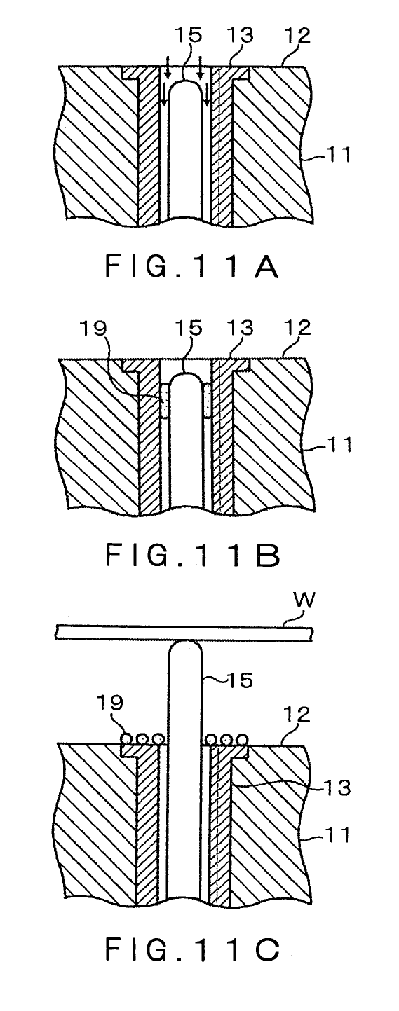

### DESCRIPTION OF THE PREFERRED EMBODIMENT

Hereinafter, embodiments of the present invention are explained in detail with reference to the attached drawings.

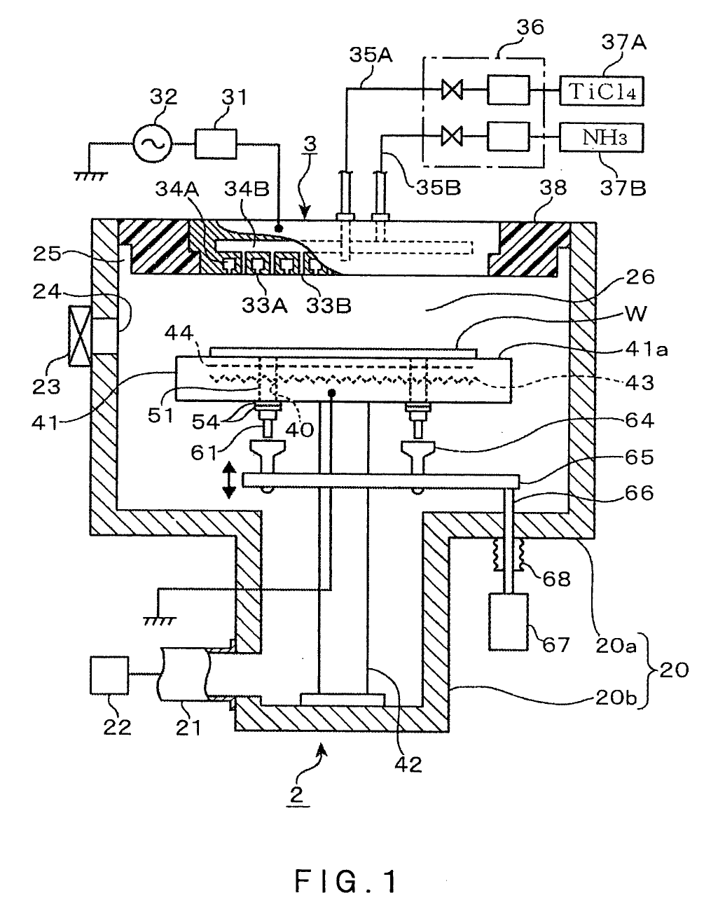

FIG. 1 is a schematic view showing an overall structure of a film-forming apparatus provided with an embodiment of a substrate placing mechanism according to the present invention.

As shown in FIG. 1, the embodiment of a substrate placing mechanism according to the present invention is installed in a film-forming apparatus 2 for conducting a plasma CVD film-forming process. The film-forming apparatus 2 comprises a processing container 20. The upper portion of the processing container 20 is a large-diameter cylindrical portion 20a. The lower portion of the processing container 20 is a small-diameter cylindrical portion 20b. The both cylindrical portions 20a and 20b are connected to each other. The processing container 20 is formed as a vacuum chamber made of for example aluminum. A heating mechanism not shown is provided in order to heat the inner wall of the processing container. A bottom portion of the processing container 20 is connected to one end of a gas-discharging pipe 21. The other end of the gas-discharging pipe 21 is connected to a vacuum pump 22 that is vacuum gas-discharging means. A side wall of the large-diameter cylindrical portion 20a of the processing container 20 is provided with a conveyance port 24 for a wafer W, which can be opened and closed by a gate valve 23.

An opening part 25 is formed at a ceiling portion of the processing container 20. A gas showerhead 3 is provided so as to close the opening part 25, opposite to a stage 41 that forms a placing stage described after. The gas showerhead 3 also functions as an upper electrode, and is connected to a radiofrequency (RF) high-frequency power supply 32 via a matching unit 31. Many gas ejecting ports 33A, 33B are formed in a matrix pattern at an overall lower surface of the gas showerhead 3. In the showerhead 3, gas flowing channels 34a and 34B are separately provided. The gas flowing channel 34A is communicated with the gas ejecting ports 33A. The gas flowing channel 34B is communicated with the gas ejecting ports 33B.

Gas supplying pipes 35A and 35B are connected to the gas showerhead 3. One end of the gas supplying pipe 35A is connected to the gas flowing channel 34A. One end of the gas supplying pipe 35B is connected to the gas flowing channel 34B. The other end of the gas supplying pipe 35A is connected to a gas supplying source 37A in which a TiCl₄ gas as a process gas has been stored, via a conglomerate of gas supplying instruments 36 in which, for example, valves and mass-flow controllers are included. The other end of the gas supplying pipe 35B is connected to a gas supplying source 37B in which an NH₃ gas as another process gas has been stored, via the conglomerate of gas supplying instruments 36. Then, when a wafer W is placed on the stage 41, the respective process gases are supplied from the gas supplying sources 37A and 37B to the gas supplying pipes 35A and 35B. Flow rates of these gases are controlled to predetermined flow rates by the mass-flow controllers included in the conglomerate of gas supplying instruments 36. Then, these gases are diffused in a processing space 26 on the wafer W placed on the stage 41 through the gas ejecting ports 33A and 33B, mixed with each other in the processing space 26, and supplied to the wafer W. Herein, the gas showerhead 3 is insulated from the processing container 20 by an insulating member 38 provided around the gas showerhead 3.

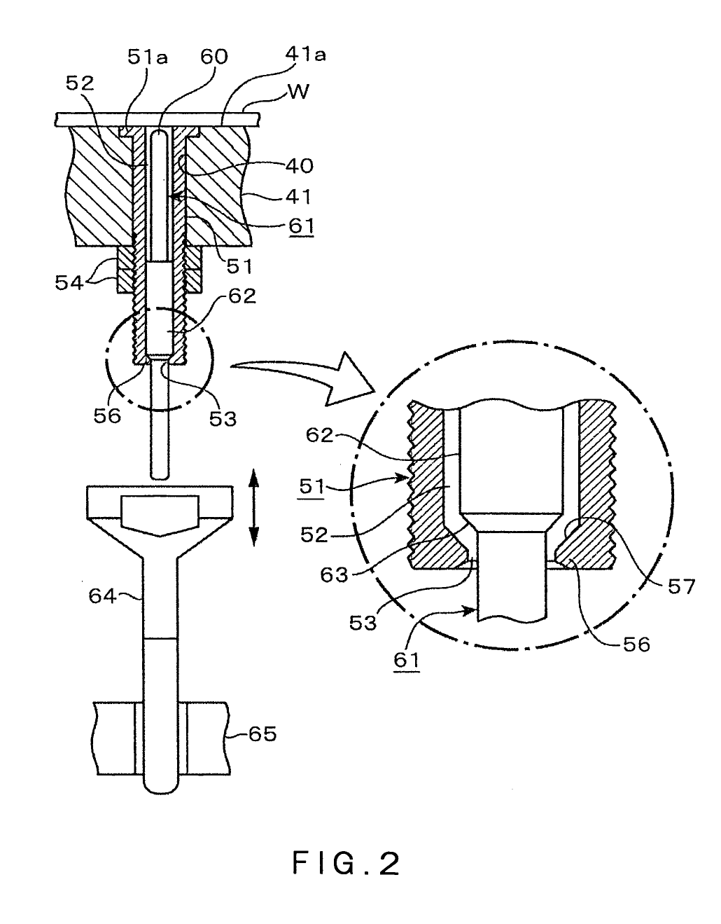

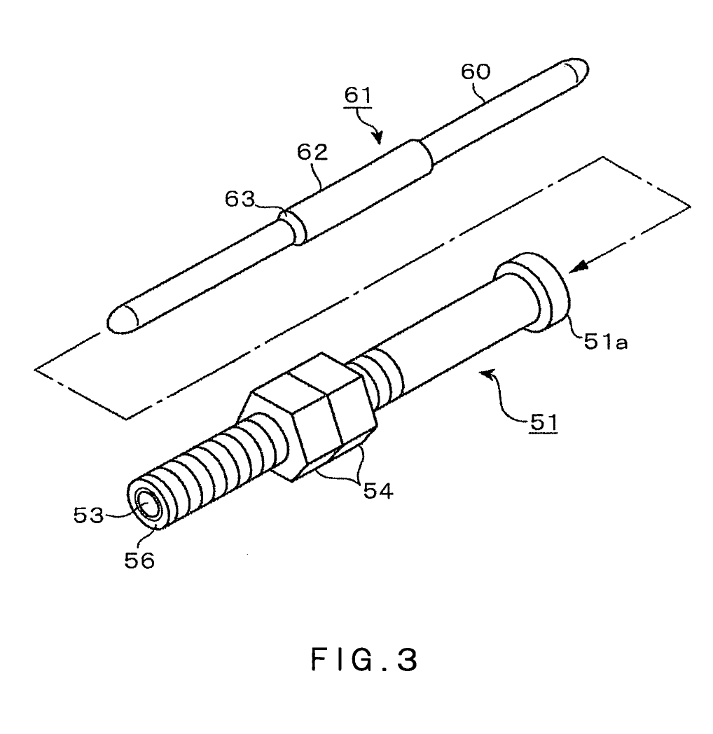

Next, the structure of the placing mechanism is explained with reference to FIGS. 2 and 3. FIG. 2 is a schematic sectional view showing the embodiment of a substrate placing mechanism according to the present invention. FIG. 3 is a perspective view of a sleeve and a lifter-pin.

For example, the stage 41 has a circular shape. The stage 41 is supported by the bottom part of the small-diameter cylindrical portion 20b of the processing container 20, via a supporting member 42. In addition, the stage 41 is located at a center of the large-diameter cylindrical portion 20a of the processing container 20.

The placing surface 41a of the stage 41 is horizontal. Thus, the wafer W placed on the placing surface 41a of the stage 41 is maintained horizontal. In the drawings, the numeral sign 43 represents a heater as temperature adjusting means of the wafer W on the stage 41. The heater 43 is buried in the stage 41. In the drawings, the numeral sign 44 represents an electrostatic chuck that absorbs the wafer W on the placing surface 41a. The stage 41 is grounded. The stage 41 serves as not only a placing stage for placing the wafer W thereon, but also a lower electrode. In FIG. 1, the wiring diagram is schematically shown. However, actually, the stage 41 is electrically connected to the processing container 20.

Three through-holes 40 are vertically formed in the stage 41, for example at regular intervals in a circumferential direction of the stage 41. A cylindrical sleeve 51 is provided in each through-hole 40. The cylindrical sleeve 51 is made of for example alumina. In the drawings, the numeral sign 52 represents a pin-inserting hole formed in the sleeve 51. In the drawings, the numeral sign 53 represents an opening part at a lower end of the sleeve 51. A flange part 51a is formed at an upper end of the sleeve 51. The flange part 51a is fitted in a large-diameter area (concave portion) of an upper portion of the through-hole 40, so that the sleeve 51 is buried in the stage 41. Herein, the upper surface of the flange part 51a is located at substantially the same height as the placing surface 41a of the stage 41.

An outside circumference of a lower part of the sleeve 51 is threaded. Two nuts 54, 54 are engaged with the threaded portion, and fastened to a lower side of the stage 41. Thus, the sleeve 51 is fixed to the stage 41. In the present embodiment, the length of the sleeve 51 is greater than the thickness of the stage 41. That is, the lower end of the sleeve 51 protrudes from the stage 41 downwardly.

At the opening part 53 of the lower end of the sleeve 51, a circular protrusion 56 is formed. The circular protrusion 56 protrudes inwardly and circularly. An upper surface of the circular protrusion 56 is funneled to become a supporting surface 57, which contacts and supports a diameter-increasing part 62 (stepped surface 63) described after when the lifter-pin 61 moves down.

As the sleeve 51 has the above feature, it is inhibited that the process gas go to an upper side in the pin-inserting hole 52 even if the process gas goes under the stage 41 and into the pin-inserting hole 52 from the opening part 53. Thus, it becomes difficult for the deposits generated from the process gas to stick on the upper side in the pin-inserting hole 52 and on a tip-end side of the lifter pin 61 described after.

Next, the lifter-pin 61 is explained. As shown in FIG. 3, the lifter-pin 61 is inserted into the pin-inserting hole 52 of the sleeve 51 from an upper side of the sleeve 51. In addition, the lifter-pin 61 is movable in a vertical direction in the pin-inserting hole 52. The lifter-pin is made of for example alumina. A diameter-increasing part 62 is provided at a central portion of the lifter pin 61. A lower end portion of the diameter-increasing part 62, that is, a stepped surface 63 extending from the diameter-increasing part 62 to the small-diameter portion, is downwardly tapered. In other words, a diameter thereof is gradually decreased. The tapered stepped surface 63 comes in contact with the supporting surface 57 of the circular protrusion 56 of the sleeve 51 when the lifter-pin 61 is away from a pin base 64. Thus, the opening part 53 of the lower end of the sleeve 51 is closed. Thus, it is inhibited that the gas flow from the opening part 53 into the pin-inserting hole 52 of the sleeve 51. In the following explanation, the position of the lifter-pin 61 at this time is called “home position” (lowered position).

A portion located upper than the diameter-increasing part 62 of the lifter-pin 61 is formed as a smaller-diameter portion 60, whose diameter is smaller than that of the diameter-increasing part 62. The axial length of the diameter-increasing part 62 is set to such a dimension that the diameter-increasing part 62 doesn't protrude from the placing surface 41a even when the lifter-pin 61 protrudes from the placing surface 41a of the stage 41 to receive or deliver the wafer W. This prevents that the diameter-increasing part 62 of the lifter-pin 61 rubs the inner wall of the sleeve 51 and pushes up the deposits of the film-forming gas that has stuck on the inner wall onto the placing surface 41a, and that the deposits stick to the wafer W placed on the placing surface 41a as particles.

It is necessary that a gap between the outer surface of the diameter-increasing part 62 and the inner surface of the sleeve 51 has such a dimension that the lifter-pin 61 can smoothly move up and down. However, if the dimension is too large, the moving up and down of the lifter pin 61 is unstable. Then, the inclination of the lifter-pin 61 is so large that the small-diameter portion 60 may come in contact with the inner surface of the sleeve 51 and/or the film-forming gas may easily flow into the upper side from the lower side. Thus, the dimension should be determined taking into consideration these balance.

The diameter-increasing part 62 of the present embodiment prevents the film-forming gas from flowing into the upper side. In addition, as the gap between the diameter-increasing part 62 and the sleeve 51 is small, when the lifter-pin 61 inclines, the diameter-increasing part 62 comes in contact with the inner wall of the sleeve 51 and inhibits the inclination. Thus, it is inhibited that the small-diameter portion 60 located upper than the diameter-increasing part 62 come in contact with the inner surface of the sleeve 51. That is, since the gap between the diameter-increasing part 62 and the sleeve 51 is small, when the lifter-pin 61 inclines, contact points between the lifter-pin 61 and the sleeve 51 are on the outer surface of the diameter-increasing part 62. That is, the small-diameter portion 60 located upper than the contact points doesn't come in contact with the sleeve 51. Thus, there is no possibility that the small-diameter portion 60 rubs the inner wall of the sleeve 51 and pushes up the deposits onto the placing surface 41a.

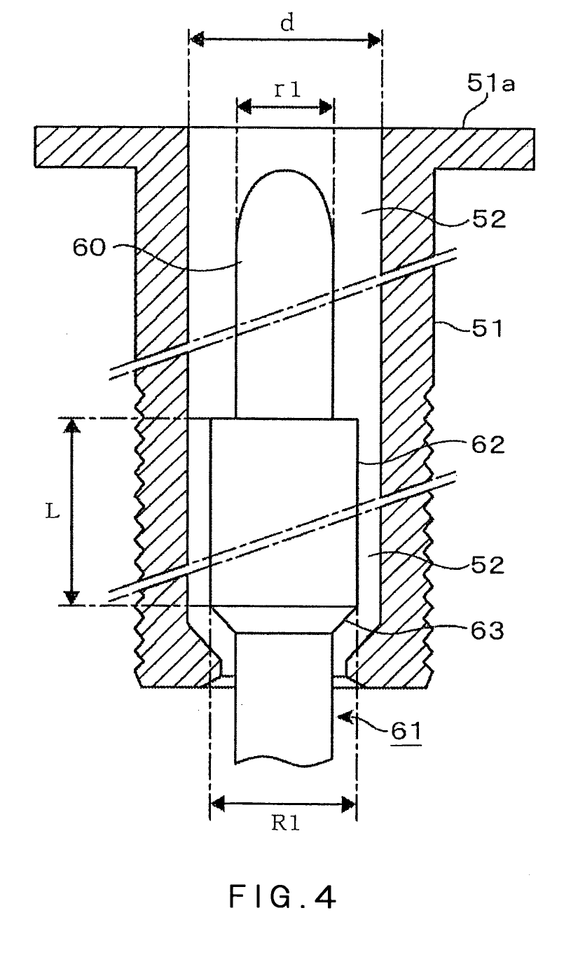

Herein, an example of dimensions of the respective components is disclosed. As shown in FIG. 4, the aperture d of the sleeve 51 is 4 mm, and the length L and the outer diameter R1 of the diameter-increasing part 62 are 20 mm and 3.6 mm, respectively. The outer diameter r1 of the small-diameter portion 60 is 2 mm.

The pin base 64 for lifting up the lifter-pin 61 is provided under the lifter-pin 61 located at the home position, for example with a gap to the lifter-pin 61. Lower portions of the respective pin bases 64 are connected to a lifter arm 65 that supports the pin bases 64 in common. In the present embodiment, the pin bases 64 and the lifter arm 65 form an elevating member. In the drawings, the numeral sign 66 is a driving rod. One end of the driving rod 66 is connected to the lifter arm 65, and the other end of the driving rod 66 extends outside the processing container 20 to be connected to an elevating mechanism 67, through a bearing part not shown at the bottom wall of the cylindrical part 20a. In the drawings, the numeral sign 68 is a bellows for ensuring airtightness between the driving rod 66 and the processing container 20. The elevating mechanism 67 causes the lifter arm 65 to move up via the driving rod 66. Because of the moving up of the lifter arm 65, the pin bases 64 move up vertically. The pin bases 64 come in contact with the lower ends of the lifter-pins 61 located at their home positions, and push up them. vertically. Thus, the lifter-pins 61 move up, and the tip ends thereof protrude from the placing surface 41a.

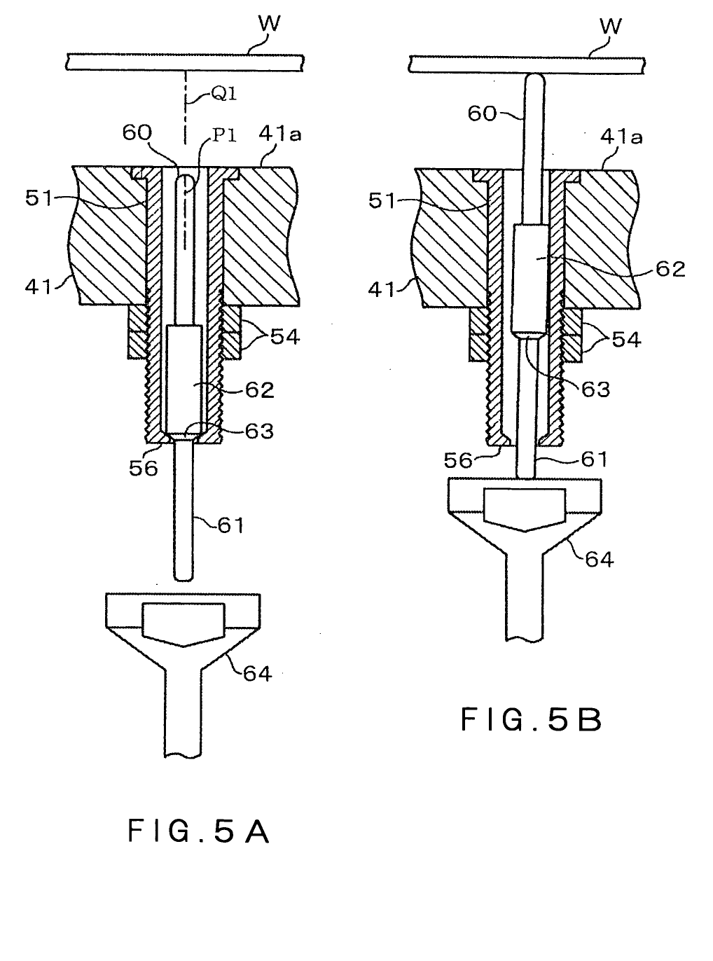

Next, a series of operations conducted by the film-forming apparatus 2 is explained. At first, the gate valve 23 is opened. A wafer W as a substrate to be processed is conveyed into the processing container 20 via the conveyance port 24 by the conveying mechanism not shown. When the wafer W is conveyed on the center of the stage 41, the pin bases 64 are caused to move up by the elevating mechanism 67 via the driving rod 66 and the lifter arm 65. FIG. 5A shows a lifter-pin 61 located at the home position. When the pin bases 64 move up, the pin bases 64 come in contact with the lower ends of the lifter-pins 61 and push up the lifter-pins 61 vertically. Thus, the lifter-pins 61 protrude from the placing surface 41a. As shown in FIG. 5B, when the tip ends of the lifter-pins 61 support the reverse surface of the wafer W, the moving-up of the pin bases 64 is stopped. At that time, the lifter-pin 61 loses its upward bias and inclines, so that the upper end of the diameter-increasing part 62 comes in contact with the inner wall of the sleeve 51, as shown in FIG. 5B. Herein, the lifter-pin 61 and the conveying mechanism (not shown) are arranged not to interfere with each other in the horizontal plane.

After that, when the pin bases 64 move down, the lifter-pins 61 move down while supporting the wafer W. When the lifter-pins 61 are accommodated in the sleeve 51, the wafer W is placed on the placing surface 41a. In addition, when the pin bases 64 move down and the lifter pins 61 also move down, the stepped surface 63 at the lower end of the diameter-increasing part 62 comes in contact with the supporting surface 57 of the circular protrusion 56 of the sleeve 51. Then, because of weight of the lifter pin 61, the stepped surface 63 of the diameter-increasing part 62 is guided by the supporting surface 57 and fitted in (supported by) the funneled portion of the supporting surface 57. In this situation, the axis P1 of the lifter-pin 61 and the axis Q1 of the sleeve 51 coincide with each other (see FIG. 5A before the moving-up of the lifter-pin). That is, the lifter-pin 61 is positioned at the center of the sleeve 51. At that time, the pin bases 64 are located under the lifter-pins 61.

On the other hand, when the conveying mechanism is retreated from the processing container 20 and the gate valve 23 is closed, the process gas is ejected into the processing space 26 from the gas ejecting ports 33A and 33B. While the process gas is supplied, the processing container 20 is evacuated by the vacuuming pump 22 to a predetermined pressure. In addition, the heater 43 and the inner wall of the processing container 20 are heated to respective set temperatures. Then, electric power from the RF high-frequency electric power source 32 is applied between the gas showerhead 3 as an upper electrode and the stage 41 as a lower electrode. Thus, the TiCl₄ gas and the NH₃ gas are activated to plasma, so that TiN is deposited on the wafer W, that is, a thin film of TiN is formed on the wafer W.

After the film-forming process is conducted for a predetermined time, the supply of the RF electric power and the supply of the respective gases are stopped. Then, a conveying-out operation reverse to the above conveying-in operation is conducted by the lifter-pins 61 and the conveying mechanism, so that the wafer W is conveyed out from the processing container 20.

In the placing mechanism for the wafer W of the present embodiment, the circular protrusion 56 is formed at the opening part 53 of the lower end of the sleeve 51 provided in the through-hole formed in the stage 41. When the lifter-pin 61 moves down, the diameter-increasing part 62 formed on the lifter-pin 61 is supported by the circular protrusion 56 to close the opening part 53. Thus, the process gas that has gone under the stage 41, on which the wafer W has been placed, is unlikely to go into the sleeve 51 from the lower end thereof. Thus, it is inhibited that the deposits generated from the process gas be accumulated at the gap between the lifter-pin 61 and the sleeve 51. Thus, it is inhibited that the movement of the lifter-pin 61 be disturbed. As a result, frequency of maintenance operation for ensuring a normal operation of the lifter-pin 61, such as a cleaning operation and/or a replacing operation of the lifter-pin 61 and the sleeve 51, may be reduced.

In addition, when the lifter-pin 61 returns to the home position, the diameter-increasing part 62 is guided on the inclined surface of the circular protrusion 56. Thus, the posture of the lifter-pin 61 is limited to a vertical one, so that the center axis of the lifter-pin 61 and the center axis of the sleeve 51 coincide with each other. In the present embodiment, when the lifter-pin 61 inclines at the home position, the diameter-increasing part 62 and the sleeve 51 come in contact with each other, but the small-diameter part 60 doesn't come in contact with the sleeve 51. Thus, when the lifter-pin 61 moves up, the small-diameter part 60 of the upper side of the lifter-pin 61 doesn't come in contact with the sleeve 51. Herein, even if the dimensions are different from the present embodiment, if the lifter-pin 61 moves up with its vertical posture and the portion upper than the diameter-increasing part 62 has a smaller diameter, when the lifter-pin 61 moves up, the upper portion of the lifter-pin 61 doesn't come in contact with the sleeve 51. In addition, the diameter-increasing part 62 is also unlikely to come in contact with the inner wall of the sleeve 51. In the case too, it is inhibited that the deposits that have stuck on the inner wall of the sleeve 51 be peeled off and pushed up by the lifter-pin 61 onto the placing surface 41a. As a result, it is inhibited that the deposits contaminate the wafer W as particles.

In the above embodiment, the lifter-pin 61 and the pin base 64 are separate. However, if the lifter-pin 61 can close the opening part 53 at its home position, the effect of the present invention can be obtained. Thus, for example, the lifter-pin 61 and the pin base 64 may be connected to each other in such a manner that the lifter-pin 61 is perpendicularly supported by the pin base 64. Such structure is included within the scope (protection scope) of the present invention.

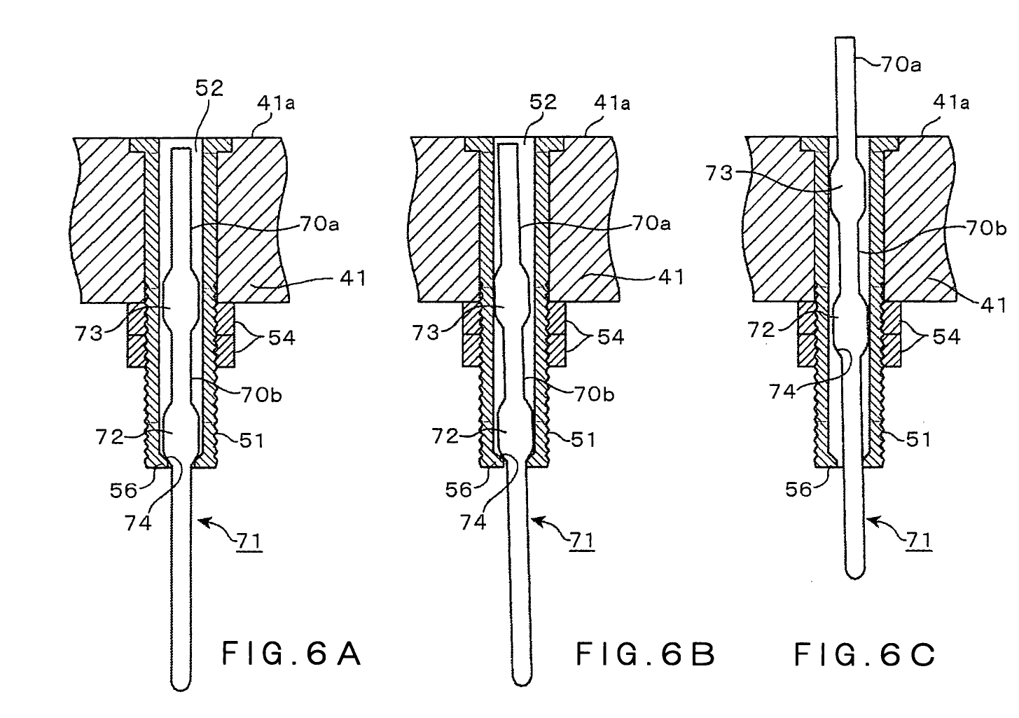

In addition, the lifter-pin is not limited to the above embodiment. The shape as shown in FIG. 6A may be adopted. In the lifter-pin 71 as shown in FIG. 6A, a first diameter-increasing part 72 and a second diameter-increasing part 73 are provided in that order toward the upper end of the lifter-pin 71. There is a central gap between the first diameter-increasing part 72 and the second diameter-increasing part 73. The portion upper than the second diameter-increasing part 73 is formed as a small-diameter portion 70a whose diameter is smaller than those of the first diameter-increasing part 72 and the second diameter-increasing part 73. The portion between the first diameter-increasing part 72 and the second diameter-increasing part 73 is formed as a small-diameter portion 70b whose diameter is smaller than those of the first diameter-increasing part 72 and the second diameter-increasing part 73. A stepped (tapered) surface 74 is formed at the lower end portion of the first diameter-increasing part 72, in the same manner as the lower end portion of the diameter-increasing part 62 of the lifter-pin 61. As shown in FIG. 6A, when the lifter-pin 71 is located at the home position, the stepped surface 74 is supported by the circular protrusion 56 of the sleeve 51. Thus, the lifter-pin 71 can close the opening part 53 of the sleeve 51 with its vertical posture, in the same manner as the above embodiment.

Then, as shown in FIG. 6B, the dimensions are set such that the small-diameter portion 70a upper than the second diameter-increasing part 73 doesn't come in contact with the inner wall of the sleeve 51 even if the lifter-pin 71 inclines at the home position although the second diameter-increasing part 73 comes in contact with the inner wall of the sleeve 51. In addition, as shown in FIG. 6C, the second diameter-increasing part 73 is adapted to stay in the sleeve 51 even when the lifter-pin 71 is lifted up by the pin base 64 and the tip end of the lifter-pin 71 protrudes from the placing surface 41a.

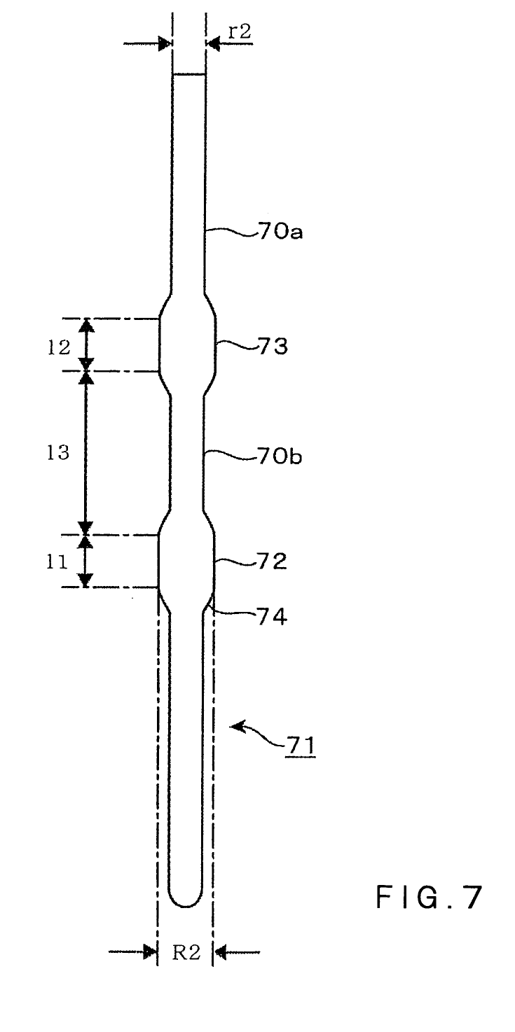

Herein, an example of dimensions of the lifter-pin 71 is disclosed. As shown in FIG. 7, the length 11 of the first diameter-increasing part 72 is 6 mm, and the length 12 of the second diameter-increasing part 73 is 6 mm. The length 13 of the small-diameter portion 70b between the first diameter-increasing part 72 and the second diameter-increasing part 73 is 7.4 mm. The outer diameter r2 of the small-diameter portions 70a and 70b is 2 mm. The outer diameter R2 of the first diameter-increasing part 72 and the second diameter-increasing part 73 is 3.6 mm. The inner diameter (aperture) of the sleeve 51 is the same as the above embodiment (4 mm).

In general, when a gas capable of generate deposits goes into a gap between solid bodies, the deposits of the gas tend to stick to a certain portion in the gap concentrically. However, if the above lifter-pin 71 is used, even when the process gas such as the TiCl₄ gas goes into the pin-inserting hole 52 from the opening part 53 when the lifter-pin 71 is located at the home position, the process gas is diffused in a large space between the first diameter-increasing part 72 and the second diameter-increasing part 73 through a gap between the first diameter-increasing part 72 and the sleeve 51. As a result, the deposits generated from the process gas tend to concentrically stick to the gap between the first diameter-increasing part 72 and the sleeve 51. As the first diameter-increasing part 72 is shorter than the diameter-increasing part 62, compared with the lifter-pin 61, it is more inhibited that the movement of the lifter-pin 71 be disturbed. Thus, the necessity for shortening a period for replacing the lifter-pin 71 and the sleeve 51 may be reduced.

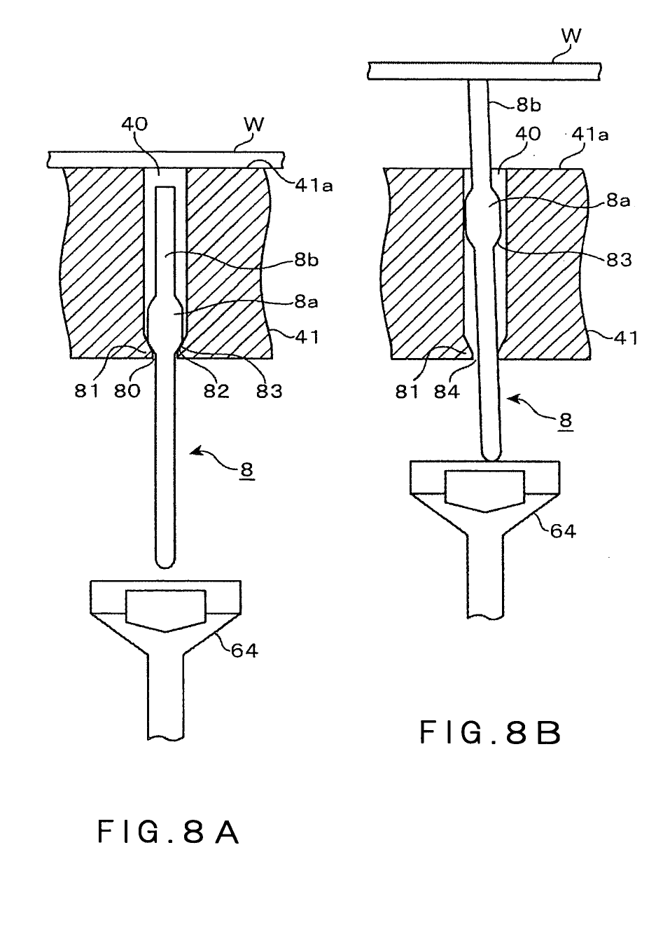

In addition, as shown in FIG. 8, the lifter-pin may be directly inserted into the through-hole 40 formed in the stage 41. Specifically, a circular protrusion 81 protruding inwardly and circularly may be formed at the opening part 80 of the lower end of the through-hole 40 in the stage 41. The upper surface of the circular protrusion 81 is preferably funneled in order to serve as a supporting surface 82, which comes in contact with the lifter-pin 8 and supports the lifter-pin 8 when the lifter-pin 8 moves down.

As shown in FIGS. 8A and 8B, in the lifer-pin 8 to be inserted into the through-hole 40, the same diameter-increasing part 8a as that in the embodiment shown in FIG. 5 is provided in a central portion of the lifter-pin 8. That is, a portion upper than the diameter-increasing part 8a is formed as a small-diameter part 8b whose diameter is smaller than the diameter-increasing part 8a. A stepped (tapered) surface 83 is formed at the lower end portion of the diameter-increasing part 8a, in the same manner as the lower end portion of the diameter-increasing part 62 of the lifter-pin 61. As shown in FIG. 8A, when the lifter-pin 8 is located at the home position, the stepped surface 83 is supported by the circular protrusion 81 of the stage 41. Thus, the lifter-pin 8 can close the opening part 80 of the stage 41 with its vertical posture, in the same manner as the above embodiment.

In addition, as shown in FIG. 8B, the diameter-increasing part 8a is adapted to stay in the stage 41 even when the lifter-pin 8 is lifted up by the pin base 64 and the tip end of the lifter-pin 8 protrudes from the placing surface 41a.

In the above embodiment, the lifter-pin 8 is directly inserted into the through-hole 40 of the stage 41. Compared with the case using the sleeve 51, the total length of the hole for inserting the lifter-pin is shortened. Thus, in a process of cleaning the inside of the film-forming apparatus 2 by supplying a cleaning gas in the film-forming apparatus 2, the cleaning gas easily reaches the lower side of the through hole 40 of the stage 41. Thus, the deposits that have stuck to the lower side of the through-hole 40 are easily removed. This is an advantage.

In addition, the number of components forming the placing mechanism is small, so that the operating time for assembling them is shortened, which can reduce cost.

1. A substrate placing mechanism comprising:
a placing stage provided for placing a substrate to be processed thereon in a processing container in which a processing atmosphere is formed by a process gas, the placing stage having a plurality of pin-inserting holes;
a plurality of lifter-pins, each of which is inserted into and vertically movable in each of the plurality of pin-inserting holes;
an elevating member that supports the plurality of lifter-pins; and
an elevating mechanism that causes the plurality of lifter-pins to vertically move via the elevating member;
wherein each of the plurality of pin-inserting holes has a circular protrusion at an opening part of a lower end thereof, the circular protrusion protruding inwardly and circularly; and
each of the plurality of lifter-pins has a diameter-increasing part that is configured to be supported by the circular protrusion so as to close the opening part when a corresponding lifter-pin is caused to move down.

2. A substrate placing mechanism according to claim 1, wherein
an upper surface of the circular protrusion is funneled in order to guide the diameter-increasing part to position the lifter-pin at a center of the pin-inserting hole.

3. A substrate placing mechanism according to claim 2, wherein
a lower surface of the diameter-increasing part is tapered.

4. A substrate placing mechanism according to claim 1, wherein
a portion of the lifter-pin that is adapted to protrude from the pin-inserting hole when the substrate is supported by the lifter-pin has a diameter smaller than that of the diameter-increasing part.

5. A substrate placing mechanism according to claim 1, wherein
a second diameter-increasing part is provided on each of the plurality of lifter-pins, the second diameter-increasing part being located upper than the diameter-increasing part, the second diameter-increasing part being maintained in the pin-inserting hole even when the substrate is received by the lifter-pin.

6. A substrate placing mechanism according to claim 1, wherein
the plurality of lifter-pins is provided separately from the elevating member, and
the diameter-increasing part is supported by the circular protrusion by weight of the lifter-pin.

7. A substrate processing apparatus, comprising
a processing container;
a substrate placing mechanism according to claim 1 provided in the processing container; and
a process-gas supplying part that supplies a process gas into the processing container in order to conduct a process to a substrate to be processed placed on the substrate placing mechanism.
